(19) United States
(12) Patent Application Publication
(10) Pub. No.: US 2021/0242176 A1
(43) Pub. Date: Aug. 5, 2021

(54) SEMICONDUCTOR PACKAGES

(71) Applicant: SK hynix Inc., Icheon-si Gyeonggi-do (KR)

(72) Inventor: Won Duck JUNG, Icheon-si Gyeonggi-do (KR)

(73) Assignee: SK hynix Inc., Icheon-si Gyeonggi-do (KR)

(21) Appl. No.: 16/934,555

(22) Filed: Jul. 21, 2020

(30) Foreign Application Priority Data
Feb. 4, 2020 (KR) 10-2020-0013338

(51) Int. Cl. H01L 25/065; H01L 23/00; H01L 23/31

(52) U.S. Cl. CPC H01L 25/0657; H01L 24/48; H01L 24/16; H01L 24/73; H01L 2224/73265; H01L 2224/04042; H01L 2224/0401; H01L 2224/48151; H01L 2224/16145; H01L 23/3128

(57) ABSTRACT

A semiconductor package includes a lower chip and an upper chip stacked on the lower chip. The lower chip includes lower chip pads arrayed in a plurality of lower columns on a top surface of the lower chip, wire bonding pads disposed on the top surface of the lower chip to be laterally spaced apart from the lower chip pads, and traces disposed on the top surface of the lower chip to electrically connect the lower chip pads to the wire bonding pads. The upper chip includes upper chip pads arrayed in a plurality of upper columns on a top surface of the upper chip and bumps disposed on the upper chip pads to contact the traces. The upper chip is stacked on the lower chip such that the top surface of the upper chip faces the top surface of the lower chip.

### CROSS-REFERENCE TO RELATED APPLICATIONS

The present application claims priority under 35 U.S.C. 119(a) to Korean Application No, 10-2020-0013338, filed on Feb. 4, 2020, which is incorporated herein by references in its entirety.

### BACKGROUND

### 1. Technical Field

The present disclosure relates to semiconductor packages and, more particularly, to a semiconductor package including a plurality of semiconductor chips stacked on a substrate.

### 2. Related Art

In general, a semiconductor package may be configured to include a substrate and a semiconductor chip mounted on the substrate. The substrate and the semiconductor chip may be electrically connected to each other by connection members such as metal wires. Recently, semiconductor packages having a stack structure have been proposed to realize high performance semiconductor packages and highly integrated semiconductor packages. The stack structure of the semiconductor packages may be configured to include a plurality of semiconductor chips stacked on a substrate. In order to improve the stack structure of the semiconductor packages, it may be necessary to reduce a size of the semiconductor packages and to lower manufacturing costs of the semiconductor packages.

### SUMMARY

According to an embodiment of the present disclosure, a semiconductor package includes a lower chip and an upper chip stacked on the lower chip. The lower chip includes lower chip pads arrayed in a plurality of lower columns on a top surface of the lower chip to have different horizontal axes, wire bonding pads disposed on the top surface of the lower chip to be laterally spaced apart from the lower chip pads, and traces disposed on the top surface of the lower chip to electrically connect the lower chip pads to the wire bonding pads. The upper chip includes upper chip pads arrayed in a plurality of upper columns on a top surface of the upper chip to have different horizontal axes and bumps disposed on respective ones of the upper chip pads to be in contact with respective ones of the traces. The upper chip is stacked on the lower chip such that the top surface of the upper chip faces the top surface of the lower chip.

According to another embodiment of the present disclosure, a semiconductor package includes a lower chip and an upper chip stacked on the lower chip. The lower chip includes a first lower chip pad array including first lower chip pads arrayed in a column direction on a top surface of the lower chip, a second lower chip pad array including second lower chip pads which are arrayed on the top surface of the lower chip to have horizontal axes different from horizontal axes of the first lower chip pads, first wire bonding pads arrayed in the column direction on the top surface of the lower chip to be laterally spaced apart from respective ones of the first lower chip pads, first traces disposed on the top surface of the lower chip to electrically connect the first lower chip pads to the first wire bonding pads, second wire bonding pads arrayed in the column direction on the top surface of the lower chip to be laterally spaced apart from respective ones of the second lower chip pads, and second traces disposed on the top surface of the lower chip to electrically connect the second lower chip pads to the second wire bonding pads. The upper chip includes a first upper chip pad array including first upper chip pads arrayed in the column direction on a top surface of the upper chip, a second upper chip pad array including second upper chip pads which are arrayed on the top surface of the upper chip to have horizontal axes different from horizontal axes of the first upper chip pads, first bumps disposed on respective ones of the first upper chip pads to be in contact with respective ones of the first traces, and second bumps disposed on respective ones of the second upper chip pads to be in contact with respective ones of the second traces. The upper chip is stacked on the lower chip such that the top surface of the upper chip faces the top surface of the lower chip.

According to yet another embodiment of the present disclosure, a semiconductor package includes a first stack structure and a second stack structure stacked on the first stack structure. The first stack structure includes a first lower chip and a first upper chip stacked on the first lower chip. The second stack structure includes a second lower chip and a second upper chip stacked on the second lower chip. Each of the first lower chip and the second lower chip includes first top surface, lower chip pads arrayed in a plurality of columns on the first top surface to have horizontal axes different from each other, wire bonding pads disposed on the first top surface to be laterally spaced apart from respective ones of the lower chip pads, and traces connecting the lower chip pads to the wire bonding pads. Each of the first upper chip and the second upper chip includes second top surface, upper chip pads arrayed in a plurality of columns on the second top surface to have horizontal axes different from each other and bumps disposed on respective ones of the upper chip pads to land on respective ones of the traces.

### BRIEF DESCRIPTION OF THE DRAWINGS

Certain features of the disclosed technology are illustrated by various embodiments with reference to the attached drawings, in which:

FIG. 1 is a cross-sectional view illustrating a semiconductor package according to an embodiment of the present disclosure;

FIG. 2 is a plan view illustrating an example of a lower chip of the semiconductor package shown in FIG. 1;

FIG. 3 is a plan view illustrating an example of an upper chip of the semiconductor package shown in FIG. 1;

FIG. 4 is an exploded perspective view illustrating the lower chip illustrated in FIG. 2 and the upper chip illustrated in FIG. 3; and

FIG. 5 is a cross-sectional view illustrating a semiconductor package according to another embodiment of the present disclosure.

### DETAILED DESCRIPTION OF THE EMBODIMENTS

The terms used herein may correspond to words selected in consideration of their functions in the following embodiments, and the meanings of the terms may be construed to be different according to one of ordinary skill in the art to which the embodiments belong. If defined in detail, then the terms may be construed according to the definitions. Unless otherwise defined, the terms (including technical and scientific terms) used herein have the same meaning as commonly understood by one of ordinary skill in the art to which the embodiments belong.

It will be understood that although the terms “first” and “second,” “top” and “bottom,” “upper” and “lower,” “upper surface” and “lower surface,” “top surface” and “bottom surface,” and “left” and “right” etc. may be used herein to describe various elements, these elements should not be limited by these terms. These terms are only used to distinguish one element from another element, but not used to define only the element itself or to mean a particular sequence.

It will be further understood that when an element is referred to as being “on,” “connected to,” or “coupled to” another element, it can be directly on, connected, or coupled to the other element, or intervening elements may be present. In contrast, when an element is referred to as being “directly on,” “directly connected to,” or “directly coupled to” another element, no intervening elements are present. It will also be understood that when a member is referred to as “comprising,” “including,” or “having” an element, it does not mean that the member excludes other elements but means that the member may further include at least one of the other elements unless any specific descriptions to the contrary are present. to Moreover, in describing the embodiments disclosed in the specification, detailed descriptions of related technologies well known in the art will be omitted when it is considered that the detailed descriptions of the related technologies make the subject matters of the embodiments unclear.

Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing. Furthermore, the number of, a shape of, a size of, and a relative size of specific elements illustrated in the drawings may be exaggerated for clarity and convenience of illustration, but not limits the scope of the inventive concept. Accordingly, the embodiments may be realized to have various configurations.

Semiconductor chips described in the following embodiments may be obtained by separating a semiconductor substrate such as a wafer including integrated circuits into a plurality of pieces using a die sawing process. The semiconductor chips may correspond to memory chips, logic chips, or application-specific integrated circuits (ASIC) chips. The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits, or phase change random access memory (PcRAM) circuits which are integrated on the semiconductor substrate. The semiconductor chips may also be referred to as semiconductor dies. In addition, each of semiconductor packages described in the present disclosure may include a substrate on which the semiconductor chip is mounted. The substrate may include at least one layer of integrated circuit patterns and may correspond to a printed circuit board (PCB). The semiconductor package may include a plurality of semiconductor chips stacked on the substrate. The semiconductor package may be employed in various electronic information processing systems. For example, the semiconductor package may be employed in communication systems such as mobile phones, electronic systems associated with health care, or wearable electronic systems.

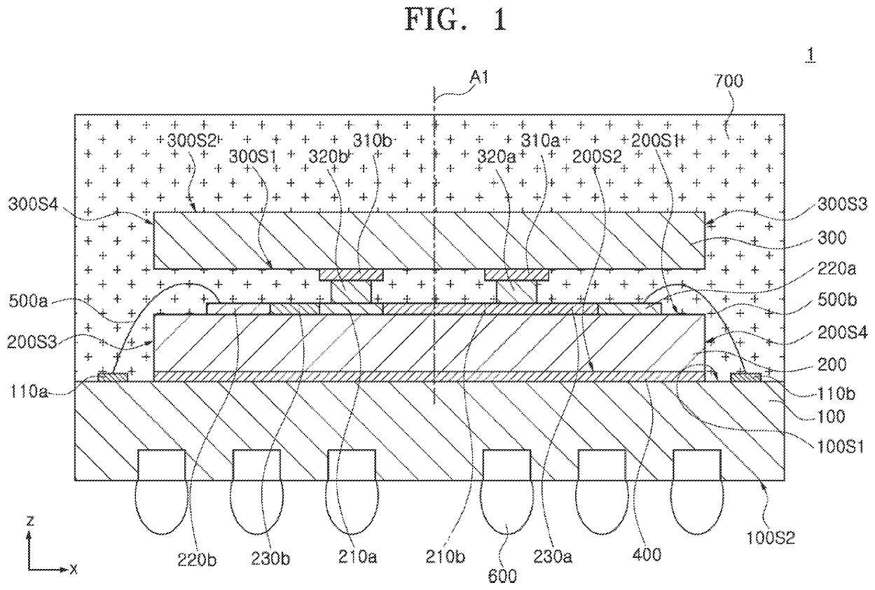

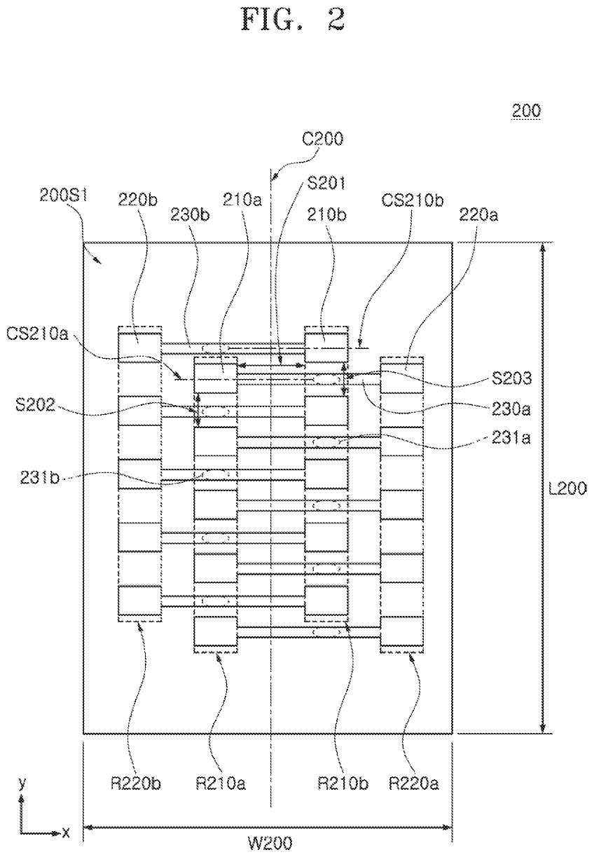

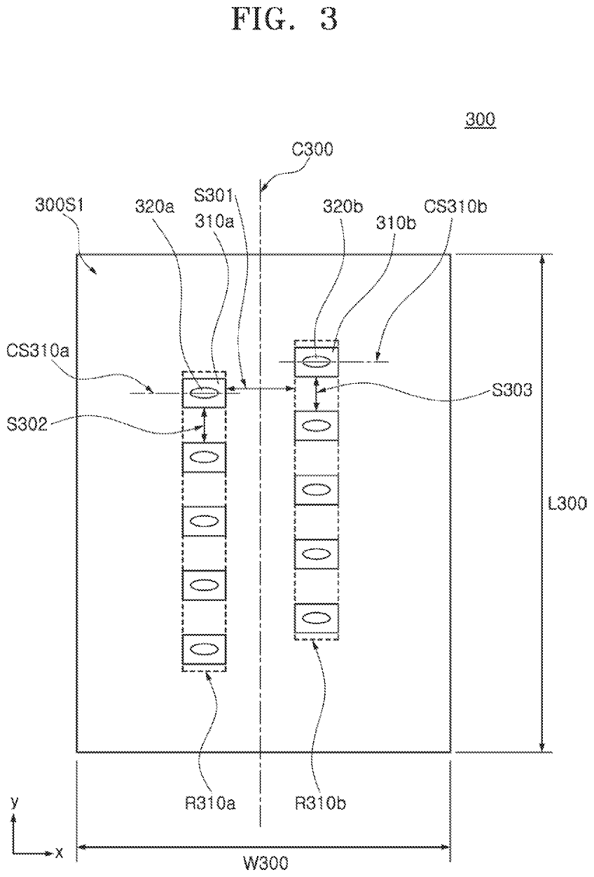

FIG. 1 is a cross-sectional view illustrating a semiconductor package 1 according to an embodiment of the present disclosure. FIG. 2 is a plan view illustrating an example of a lower chip 200 included in the semiconductor package 1 shown in FIG. 1. FIG. 3 is a plan view illustrating an example of an upper chip 300 included in the semiconductor package 1 shown in FIG. 1.

Referring to FIG. 1, the semiconductor package 1 may include the lower chip 200 and the upper chip 300 stacked on the lower chip 200. The lower chip 200 and the upper chip 300 may be in contact with each other or electrically connected to each other. In addition, the semiconductor package 1 may further include a substrate 100, an adhesive layer 400 disposed between the substrate 100 and the lower chip 200 to attach the lower chip 200 to the substrate 100, bonding wires 500a and 500b electrically connecting the lower chip 200 to the substrate 100, outer connectors 600 attached to the substrate 100 to electrically connect the semiconductor package 1 to another semiconductor package or another substrate (e.g., a PCB), and an encapsulating member 700 disposed to surround or cover the lower chip 200, the upper chip 300 and the bonding wires 500a and 500b. The encapsulating member 700 may be formed to include an insulator and to fill an empty space in the semiconductor package 1.

Referring again to FIG. 1, the substrate 100 may have a top surface 100S1 facing the lower chip 200 and a bottom surface 100S2 located at an opposite side of the top surface 100S1. Connection pads 110a and 110b may be disposed on the top surface 100S1 of the substrate 100 to be connected to the bonding wires 500a and 500b. The connection pads 110a and 110b may be formed to include a conductive member or a conductive material. In addition, various pads, traces (e.g., redistributed lines), bumps, and interconnection lines, which are described hereinafter, may also be formed to include a conductive member or a conductive material.

Referring still to FIG. 1, the outer connectors 600 for electrically connecting the semiconductor package 1 to another semiconductor package or another substrate (e.g., a PCB) may be disposed on the bottom surface 100S2 of the substrate 100. The outer connectors 600 may be formed to include bumps or solder balls. Although not shown in the drawings, the substrate 100 may include interconnection lines disposed in a body of the substrate 100. The connection pads 110a and 110b may be electrically connected to the outer connectors 600 through the interconnection lines disposed in the substrate 100.

Referring again to FIG. 1, the lower chip 200 disposed on the top surface 100S1 of the substrate 100 may include a top surface 200S1, a bottom surface 200S2, a first side surface 200S3, and a second side surface 200S4. When considering FIG. 1 as a reference drawing, the first side surface 200S3 may correspond to a left side surface of the lower chip 200, and the second side surface 200S4 may correspond to a right side surface of the lower chip 200. In an embodiment, the lower chip 200 may have a cuboid shape, but is not limited thereto. The top surface 200S1 of the lower chip 200 may act as an active surface. An inside upper region of the lower chip 200 adjacent to the active surface (i.e., the top surface 200S1) may correspond to an active region. Integrated circuits including various active devices and various passive devices may be disposed in and on the active region. In contrast, it might be that no integrated circuit exists in an inside lower region of the lower chip 200 adjacent to the bottom surface 200S2.

The lower chip 200 may be bonded to the substrate 100 by the adhesive layer 400. The adhesive layer 400 may be disposed between the top surface 100S1 of the substrate 100 and the bottom surface 200S2 of the lower chip 200. The adhesive layer 400 may include a non-conductive material such as a polymer material.

Referring again to FIGS. 1 and 2, lower chip pads 210a and 210b may be disposed on the top surface 200S1 of the lower chip 200. First lower chip pads 210a of the lower chip pads may be arrayed in a first column parallel with a y-axis, and second lower chip pads 210b of the lower chip pads may be arrayed in a second column parallel with the y-axis, The first and second lower chip pads 210a and 210b may be arrayed in a zigzag fashion along a y-axis direction when viewed in a plan view. Accordingly, the lower chip pads 210a and 210b may be put on respective ones of horizontal axes which are spaced apart from each other to be parallel with an x-axis. The first and second lower chip pads 210a and 210b may have substantially the same shape and size, but are not limited thereto.

Referring again to FIGS. 1 and 2, wire bonding pads 220a and 220b may be disposed on the top surface 200S1 of the lower chip 200 to be spaced apart from the lower chip pads 210a and 210b in an x-axis direction. The wire bonding pads 220a and 220b may include first wire bonding pads 220a and second wire bonding pads 220b. The first wire bonding pads 220a may be disposed on the top surface 200S1 of the lower chip 200 to be parallel with the first lower chip pads 210a along the X-axis direction. The second wire bonding pads 220b may be disposed on the top surface 200S1 of the lower chip 200 to be parallel with the second lower chip pads 210b along the X-axis direction. The bonding wires 500a and 500b may be bonded to respective ones of the wire bonding pads 220a and 220b to electrically connect the wire bonding pads 220a and 220b to the connection pads 110a and 110b of the substrate 100. The first wire bonding pads 220a and the second wire bonding pads 220b may have the same shape and size, but are not limited thereto.

Referring yet to FIGS. 1 and 2, traces 230a and 230b may be disposed on the top surface 200S1 of the lower chip 200 to electrically connect the lower chip pads 210a and 210b to the wire bonding pads 220a and 220b. The traces 230a and 230b may be redistribution lines. The traces 230a and 230b may include first traces 230a and second traces 230b. The first traces 230a may be disposed on the top surface 200S1 of the lower chip 200 to connect the first lower chip pads 210a to the first wire bonding pads 220a. The second traces 230b may be disposed on the top surface 200S1 of the lower chip 200 to connect the second lower chip pads 210b to the second wire bonding pads 220b. The traces 230a and 230b may be realized to have various shapes in order to electrically connect the lower chip pads 210a and 210b to the wire bonding pads 220a and 220b. The first and second traces 230a and 230b may have substantially the same shape, size, and structure. For example, the first and second traces 230a and 230b may be configured to have the same length, but are not limited thereto.

Referring still to FIGS. 1 and 2, the first traces 230a may be disposed to be spaced apart from the second lower chip pads 210b in the y-axis direction and may extend in the x-axis direction. In an embodiment, the first traces 230a and the second lower chip pads 210b may be alternately disposed in the y-axis direction, and the first traces 230a may extend in the x-axis direction. Each of the first traces 230a may include a first landing portion 231a for connecting the lower chip 200 to the upper chip 300. As illustrated in FIG. 2, the first landing portions 231a of the first traces 230a may be located in the second column where the second lower chip pads 210b are arrayed. The second traces 230b may be disposed to be spaced apart from the first lower chip pads 210a in the y-axis direction and may extend in the x-axis direction. In an embodiment, the second traces 230b and the first lower chip pads 210a may be alternately disposed in the y-axis direction, and the second traces 230b may extend in the x-axis direction. Each of the second traces 230b may include a second landing portion 231b for connecting the lower chip 200 to the upper chip 300. As illustrated in FIG. 2, the second landing portions 231b of the second traces 230b may be located in the first column where the first lower chip pads 210a are arrayed.

Referring to FIGS. 1 and 3, the upper chip 300 may be disposed on the lower chip 200. The upper chip 300 may include a top surface 300S1, a bottom surface 300S2, a first side surface 300S3, and a second side surface 300S4. The top surface 300S1 of the upper chip 300 may act as an active surface. Integrated circuits including various active devices and various passive devices may be disposed in and on an active region of the upper chip 300, which is adjacent to the active surface. In contrast, it might be that no integrated circuit exists in an inside region of the upper chip 300, which is adjacent to the bottom surface 300S2.

In the semiconductor package 1, the upper chip 300 may be stacked on the lower chip 200 such that the top surface 300S1 of the upper chip 300 faces the top surface 200S1 of the lower chip 200. Thus, when the upper chip 300 is the same chip as the lower chip 200, the upper chip 300 and the lower chip 200 may be symmetric with respect to a straight horizontal line (not shown) which is located between the upper chip 300 and the lower chip 200 and is parallel with the X-axis. That is, the upper chip 300 may correspond to a flip chip. Hereinafter, it may be assumed that the upper chip 300 is the same chip as the lower chip 200 for the purpose of ease and convenience in explanation. Because the upper chip 300 is the same chip as the lower chip 200, the first side surface 300S3 and the second side surface 300S4 of the upper chip 300 may correspond to respective ones of the left side surface 200S3 and the right side surface 200S4 of the lower chip 200. However, because the upper chip 300 is a flip chip, the first side surface 300S3 of the upper chip 300 may be aligned with the right side surface 200S4 (i.e., the second side surface) of the lower chip 200 along a z-axis direction and the second side surface 300S4 of the upper chip 300 may be aligned with the left side surface 200S3 (i.e., the first side surface) of the lower chip 200 along the z-axis direction. As described above, the upper chip 300 and the lower chip 200 may have the same shape and size, but are not limited thereto.

Referring again to FIGS. 1 and 3, upper chip pads 310a and 310b may be disposed on the top surface 300S1 of the upper chip 300. First upper chip pads 310a of the upper chip pads may be arrayed in a first column parallel with the y-axis, and second upper chip pads 310b of the upper chip pads may be arrayed in a second column parallel with the y-axis. The first and second upper chip pads 310a and 310b may be arrayed in a zigzag fashion along the y-axis direction when viewed in a plan view, Accordingly, the upper chip pads 310a and 310b may be put on respective ones of horizontal axes which are spaced apart from each other to be parallel with the x-axis. In an embodiment, the first and second lower chip pads 210a and 210b may have substantially the same shape and size. In addition, the upper chip pads 310a and 310b disposed on the top surface 300S1 of the upper chip 300 may have the same shape as the lower chip pads 210a and 210b disposed on the top surface 200S1 of the lower chip 200.

Referring still to FIGS. 1 and 3, bumps 320a and 320b may be disposed on respective ones of the upper chip pads 310a and 310b to be in contact with the respective ones of the traces 230a and 230b disposed on the top surface 200S1 of the lower chip 200. The bumps 320a and 320b may include first bumps 320a and second bumps 320b. First ends of the first bumps 320a may be in contact with the first upper chip pads 310a, and second ends of the first bumps 320a may be in contact with the first landing portions 231a of the first traces 230a. First ends of the second bumps 320b may be in contact with the second upper chip pads 310b, and second ends of the second bumps 320b may be in contact with the second landing portions 231b of the second traces 230b.

Referring again to FIG. 1, the bonding wires 500a and 500b may include first bonding wires 500a and second bonding wires 500b which include a metal material. In addition, the bonding wires 500a and 500b may be bonded to the connection pads 110a and 110b and the wire bonding pads 220a and 220b. The first bonding wires 500a may electrically connect the first connection pads 110a to the second wire bonding pads 220b, and the second bonding wires 500b may electrically connect the second connection pads 110b to the first wire bonding pads 220a. Thus, the lower chip 200 may directly communicate with eth substrate 100 through the bonding wires 500a and 500b. In contrast, the upper chip 300 may be bonded to the lower chip 200 by methods described hereinafter to be electrically connected to the substrate 100.

The lower chip 200 and the upper chip 300 may be semiconductor chips including an integrated circuit and may be configured to have the same function. For example, the lower chip 200 and the upper chip 300 may be memory chips, The lower chip 200 may be configured to further include the wire bonding pads 220a and 220b and the traces 230a and 230b disposed on the top surface 200S1 of the lower chip 200, as compared with the upper chip 300. In addition, the upper chip 300 may be configured to further include the bumps 320a and 320b disposed on the upper chip pads 310a and 310b, as compared with the lower chip 200. In an embodiment, the lower chip 200 may act as a master chip directly communicating with the substrate 100 through the bonding wires 500a and 500b. The upper chip 300 may be a slave chip which is controlled by the master chip.

Referring still to FIG. 1, the upper chip 300 may be vertically stacked on the lower chip 200 along the z-axis direction such that the top surface 300S1 of the upper chip 300 faces the top surface 200S1 of the lower chip 200. In addition, the lower chip 200 and the upper chip 300 may be stacked on the substrate 100 to share a single symmetric axis A1 extending in a vertical direction (Le., the z-axis direction). As illustrated in FIG. 1, when the lower chip 200 and the upper chip 300 are configured to have the same shape and size, the lower chip 200 and the upper chip 300 may be stacked to be parallel with the y-axis and may be stacked such that both ends of the upper chip 300 have the same coordinates as both ends of the lower chip 200 on the x-axis. That is, the lower chip 200 and the upper chip 300 may be stacked on the substrate such that the first side surface 200S3 of the lower chip 200 and the second side surface 300S4 of the upper chip 300 are vertically aligned with each other to be consistent with one vertical plane and the second side surface 200S4 of the lower chip 200 and the first side surface 300S3 of the upper chip 300 are vertically aligned with each other to be consistent with another vertical plane.

A configuration of the lower chip 200 will be described hereinafter in detail with reference to FIG. 2. The lower chip 200 may have a width W200 in the x-axis direction and a length L200 in the y-axis direction. In addition, the lower chip 200 may have a central axis C200 which is parallel with the y-axis and passes through a central point of the lower chip 200. That is, the central axis C200 of the lower chip 200 may be parallel with the y-axis and may pass through a central point of the width W200. Moreover, the lower chip pads 210a and 210b, the wire bonding pads 220a and 220b, and the traces 230a and 230b may be arrayed on the top surface 200S1 of the lower chip 200 along the y-axis direction.

Referring to FIG. 2, the lower chip pads 210a and 210b may be arrayed in a plurality of columns. More specifically, the lower chip pads 210a and 210b may be arrayed in two columns, which are parallel with the y-axis, on the top surface 200S1 of the lower chip 200. In such a case, the lower chip pads 210a and 210b may be disposed to have horizontal axes which are different from each other, respectively. That the lower chip pads 210a and 210b have different horizontal axes means that straight lines passing through central points of the lower chip pads 210a and 210b to be parallel with the x-axis are spaced apart from each other. The first lower chip pads 210a may be arrayed in a first column parallel with the y-axis, and the second lower chip pads 210b may be arrayed in a second column parallel with the y-axis. As illustrated in FIG. 2, the first lower chip pads 210a and the second lower chip pads 210b may be arrayed in a zigzag fashion along the y-axis direction when viewed in a plan view.

Referring to FIG. 2, the lower chip pads 210a and 210b may include the plurality of first lower chip pads 210a and the plurality of second lower chip pads 210b. The plurality of second lower chip pads 210b may be disposed to be spaced apart from each other in the y-axis direction to have horizontal axes which are different from horizontal axes of the plurality of first lower chip pads 210a. In FIG. 2, the plurality of first lower chip pads 210a may be disposed at a left side of the central axis C200 of the lower chip 200, and the plurality of second lower chip pads 210b may be disposed at a right side of the central axis C200 of the lower chip 200. The plurality of first lower chip pads 210a may be spaced apart from the plurality of second lower chip pads 210b by a horizontal distance S201 in the x-axis direction.

Referring to FIG. 2, horizontal axes CS210a of the plurality of first lower chip pads 210a may be set to be inconsistent with horizontal axes CS210b of the plurality of second lower chip pads 210b. Thus, the plurality of first lower chip pads 210a and the plurality of second lower chip pads 210b may be arrayed in a zigzag fashion along the y-axis direction on the top surface 200S1 of the lower chip 200. In such a case, the horizontal axes CS210a of the plurality of first lower chip pads 210a may be set to be parallel with each other. In addition, the plurality of first lower chip pads 210a may share one vertical axis perpendicular to the horizontal axes CS210a. As such, the plurality of first lower chip pads 210a may be arrayed on the top surface 200S1 of the lower chip 200 to have one vertical axis parallel with the y-axis. Similarly, the plurality of second lower chip pads 210b may share one vertical axis perpendicular to the horizontal axes CS210b. The plurality of second lower chip pads 210b may be arrayed on the top surface 200S1 of the lower chip 200 to have one vertical axis parallel with the y-axis.

Referring to FIG. 2, the plurality of first lowerchip pads 210a may be arrayed on the top surface 200S1 of the lower chip 200 in the y-axis direction with a column directional distance S202 to constitute a first lower chip pad array R210a. The column directional distance S202 may also be referred to as a first lower chip pad array distance. The plurality of second lower chip pads 210b may be arrayed on the top surface 200S1 of the lower chip 200 in the y-axis direction with a column directional distance S203 to constitute a second lower chip pad array R210b. The column directional distance S203 may also be referred to as a second lower chip pad array distance.

Referring to FIG. 2, the first lower chip pad array R210a and the second lower chip pad array R210b may be disposed on the top surface 200S1 of the lower chip 200 to be spaced apart from each other by the horizontal distance S201 in the x-axis direction. In addition, one of the first lower chip pad array R210a and the second lower chip pad array R210b may be located to be offset or shifted by a certain distance in the y-axis direction relative to the other of the first lower chip pad array R210a and the second lower chip pad array R210b. Thus, the plurality of first lower chip pads 210a and the plurality of second lower chip pads 210b may be arrayed in a zigzag fashion along the y-axis direction. That is, one of the first lower chip pad array R210a and the second lower chip pad array R210b may be located at a position where the other of the first lower chip pad array R210a and the second lower chip pad array R210b is shifted by a first distance in the y-axis direction and by a second distance in the x-axis direction. Thus, the plurality of first lower chip pads 210a and the plurality of second lower chip pads 210b may be arrayed on the top surface 200S1 of the lower chip 200 to have horizontal axes which are different from each other.

Referring to FIG. 2, the wire bonding pads 220a and 220b may be disposed on the top surface 200S1 of the lower chip 200 to be spaced apart from the lower chip pads 210a and 210b in the x-axis direction. The wire bonding pads 220a and 220b may include the plurality of first wire bonding pads 220a and the plurality of second wire bonding pads 220b. The plurality of first wire bonding pads 220a may be disposed on the top surface 200S1 of the lower chip 200 to be located at a position which is spaced apart from the plurality of first lower chip pads 210a by a certain distance in a positive direction of the x-axis. The plurality of second wire bonding pads 220b may be disposed on the top surface 200S1 of the lower chip 200 to be located at a position which is spaced apart from the plurality of second lower chip pads 210b by a certain distance in a negative direction of the x-axis. In FIG. 2, the plurality of first wire bonding pads 220a may be disposed at a right side of the central axis C200 of the lower chip 200, and the plurality of second wire bonding pads 220b may be disposed at a left side of the central axis C200 of the lower chip 200.

Referring to FIG. 2, the plurality of first wire bonding pads 220a may be arrayed in a column on the top surface 200S1 of the lower chip 200 to constitute a first wire bonding pad array R220a. Similarly, the plurality of second wire bonding pads 220b may be arrayed in a column on the top surface 200S1 of the lower chip 200 to constitute a second wire bonding pad array R220b.

In addition, the first wire bonding pads 220a may be disposed to have the same y-axis coordinates as the first lower chip pads 210a connected to the first wire bonding pads 220a through the first trances 230a, and the second wire bonding pads 220b may be disposed to have the same y-axis coordinates as the second lower chip pads 210b connected to the second wire bonding pads 220b through the second trances 230b. In an embodiment, the first wire bonding pads 220a may be located at positions where the first lower chip pads 210a are shifted in the x-axis direction. In addition, the second wire bonding pads 220b may be located at positions where the second lower chip pads 210b are shifted in the x-axis direction. As a result, the plurality of first wire bonding pads 220a may be disposed on the top surface 200S1 of the lower chip 200 to correspond to respective ones of the plurality of first lower chip pads 210a in the x-axis direction, and the plurality of second wire bonding pads 220b may be disposed on the top surface 200S1 of the lower chip 200 to correspond to respective ones of the plurality of second lower chip pads 210b in the x-axis direction.

Furthermore, the first wire bonding pad array R220a and the first lower chip pad array R210a may be disposed on the top surface 200S1 of the lower chip 200 to be parallel with the y-axis. In addition, the second wire bonding pad array R220b and the second lower chip pad array R210b may be disposed on the top surface 200S1 of the lower chip 200 to be parallel with the y-axis. In such a case, distances between the lower chip pads and the corresponding wire bonding pads may be equal to each other. That is, the traces 230a and 230b connecting the lower chip pads 210a and 210b to the wire bonding pads 220a and 220b may be realized to have the same length. In addition, a distance between the central axis C200 and the lower chip pads 210a and 210b may be less than a distance between the central axis C200 and the wire bonding pads 220a and 220b.

Referring to FIG. 2, the traces 230a and 230b may be disposed on the top surface 200S1 of the lower chip 200 to electrically connect the lower chip pads 210a and 210b to the wire bonding pads 220a and 220b. The traces 230a and 230b may include the landing portions 231a and 231b to which the bumps 320a and 320b illustrated in FIG. 3 are attached. The traces 230a and 230b may be disposed on the top surface 200S1 of the lower chip 200 to pass through regions S2 and S3 between the lower chip pads 210a as well as between the lower chip pads 210b. The landing portions 231a and 231b may be defined as portions of the traces 230a and 230b.

Referring to FIG. 2, the traces 230a and 230b may include the plurality of first traces 230a and the plurality of second traces 230b. The plurality of first traces 230a may connect the plurality of first lower chip pads 210a to the plurality of first wire bonding pads 220a. The plurality of second traces 230b may connect the plurality of second lower chip pads 210b to the plurality of second wire bonding pads 220b. The plurality of first traces 230a may include the plurality of first landing portions 231a to which the plurality of first bumps 320a illustrated in FIG. 3 are attached. The plurality of second traces 230b may include the plurality of second landing portions 231b to which the plurality of second bumps 320b illustrated in FIG. 3 are attached. As such, each of the traces 230a and 230b may include a landing portion to which a bump is attached. For example, each of the first traces 230a may include the first landing portions 231a to which the first bump 320a illustrated in FIG. 3 is attached, and each of the second traces 230b may include the second landing portions 231b to which the second bump 320b illustrated in FIG. 3 is attached.

Referring to FIG. 2, the plurality of first traces 230a may be disposed on the top surface 200S1 of the lower chip 200 to pass through regions between the plurality of second lower chip pads 210b and to connect the plurality of first lower chip pads 210a to respective ones of the plurality of first wire bonding pads 220a. The plurality of second traces 230b may be disposed on the top surface 200S1 of the lower chip 200 to pass through regions between the plurality of first lower chip pads 210a and to connect the plurality of second lower chip pads 210b to respective ones of the plurality of second wire bonding pads 220b.

Referring to FIG. 2, the first lower chip pad array R210a, the second lower chip pad array R210b, the first wire bonding pad array R220a, and the second wire bonding pad array R220b may be disposed to be spaced apart from each other by predetermined distances in the x-axis direction. The column directional distance S202 between the plurality of first lower chip pads 210a may be set to be equal to the column directional distance S203 between the plurality of second lower chip pads 210b, but is not limited thereto. For example, in some other embodiments, the column directional distance S202 between the plurality of first lower chip pads 210a may be set to be different from the column directional distance S203 between the plurality of second lower chip pads 210b.

According to the above descriptions, in an embodiment, the lower chip 200 may be configured to include the lower chip pad arrays R210a and R210b including the lower chip pads 210a and 210b disposed on the top surface 200S1 of the lower chip 200 to have different horizontal axes, the wire bonding pad arrays R220a and R220b including the wire bonding pads 220a and 220b disposed to be spaced apart from the lower chip pads 210a and 210b, and the traces 230a and 230b disposed on the top surface 200S1 of the lower chip 200 to connect the lower chip pads 210a and 210b to the wire bonding pads 220a and 220b.

A configuration of the upper chip 300 will be described hereinafter in detail with reference to FIG. 3. The upper chip 300 may have a width W300 in the x-axis direction and a length L300 in the y-axis direction. In addition, the upper chip 300 may have a central axis C300 which is parallel with the y-axis and passes through a central point of the upper chip 300. That is, the central axis C300 of the upper chip 300 may be parallel with the y-axis and may pass through a central point of the width W300. Moreover, the upper chip pads 310a and 310b may be arrayed on the top surface 300S1 of the upper chip 300 along the y-axis direction.

Referring to FIG. 3, the upper chip pads 310a and 310b may be arrayed in a plurality of columns. More specifically, the upper chip pads 310a and 310b may be arrayed in two columns, which are parallel with the y-axis, on the top surface 300S1 of the upper chip 300. In such a case, the upper chip pads 310a and 310b may be disposed to have horizontal axes which are different from each other, respectively. That the upper chip pads 310a and 310b have different horizontal axes means that straight lines passing through central points of the upper chip pads 310a and 310b to be parallel with the x-axis are spaced apart from each other. The first upper chip pads 310a may be arrayed in a first column parallel with the y-axis, and the second upper chip pads 310b may be arrayed in a second column parallel with the y-axis. As illustrated in FIG. 3, the first upper chip pads 310a and the second upper chip pads 310b may be arrayed in a zigzag fashion along the y-axis direction when viewed to in a plan view.

Referring to FIG. 3, the upper chip pads 310a and 310b may include the plurality of first upper chip pads 310a and the plurality of second upper chip pads 310b. The plurality of second upper chip pads 310b may be disposed to be spaced apart from each other in the y-axis direction to have horizontal axes which are different from horizontal axes of the plurality of first upper chip pads 310a. In FIG. 3, the plurality of first upper chip pads 310a may be disposed at a left side of the central axis C300 of the upper chip 300, and the plurality of second upper chip pads 310b may be disposed at a right side of the central axis C300 of the upper chip 300. The plurality of first upper chip pads 310a may be spaced apart from the plurality of second upper chip pads 310b by a horizontal distance S301 in the x-axis direction.

Referring to FIG. 3, horizontal axes CS310a of the plurality of first upper chip pads 310a may be set to be inconsistent with horizontal axes CS310b of the plurality of second upper chip pads 310b. Thus, the plurality of first upper chip pads 310a and the plurality of second upper chip pads 310b may be arrayed in a zigzag fashion along the y-axis direction on the top surface 300S1 of the upper chip 300.

Referring to FIG. 3, the horizontal axes CS310a of the plurality of first upper chip pads 310a may be set to be parallel with the x-axis and to be spaced apart from each other. In addition, the horizontal axes CS310b of the plurality of second upper chip pads 310b may be set to be parallel with the x-axis and to be spaced apart from each other. The plurality of second upper chip pads 310b may be arrayed to have horizontal axes which are different from horizontal axes of the plurality of first upper chip pads 310a. The plurality of first upper chip pads 310a may share one vertical axis perpendicular to the horizontal axes CS310a. As such, the plurality of first upper chip pads 310a may be arrayed on the top surface 300S1 of the upper chip 300 to have one vertical axis parallel with the y-axis. Similarly, the plurality of second upper chip pads 310b may share one vertical axis perpendicular to the horizontal axes CS310b. As such, the plurality of second upper chip pads 310b may be arrayed on the top surface 300S1 of the upper chip 300 to have one vertical axis parallel with the y-axis. Furthermore, the plurality of first upper chip pads 310a may be arrayed on the top surface 300S1 of the upper chip 300 in the y-axis direction with a column directional distance S302 to constitute a first upper chip pad array R310a. The column directional distance S302 may also be referred to as a first upper chip pad array distance. Similarly, the plurality of second upper chip pads 310b may be arrayed on the top surface 300S1 of the upper chip 300 in the y-axis direction with a column directional distance S303 to constitute a second upper chip pad array R310b. The column directional distance S303 may also be referred to as a second upper chip pad array distance.

Referring to FIG. 3, the first upper chip pad array R310a and the second upper chip pad array R310b may be disposed on the top surface 300S1 of the upper chip 300 to be spaced apart from each other by the horizontal distance S301 in the x-axis direction. In addition, one of the first upper chip pad array R310a and the second upper chip pad array R310b may be located to be offset or shifted by a certain distance in the y-axis direction relative to the other of the first upper chip pad array R310a and the second upper chip pad array R310b. Thus, the plurality of first upper chip pads 310a and the plurality of second upper chip pads 310b may be arrayed in a zigzag fashion along the y-axis direction. That is, one of the first upper chip pad array R310a and the second upper chip pad array R310b may be located at a position where the other of the first upper chip pad array R310a and the second upper chip pad array R310b is shifted by a first distance in the y-axis direction and by a second distance in the x-axis direction. Thus, the plurality of first upper chip pads 310a and the plurality of second upper chip pads 310b may be arrayed on the top surface 300S1 of the upper chip 300 to have horizontal axes which are different from each other.

Referring to FIG. 3, the bumps 320a and 320b may include the plurality of first bumps 320a and the plurality of second bumps 320b. The plurality of first bumps 320a may be disposed on respective ones of the plurality of first upper chip pads 310a to be in contact with respective ones of the first landing portions 231a of the plurality of first traces 230a illustrated in FIG. 2. The plurality of second bumps 320b may be disposed on respective ones of the plurality of second upper chip pads 310b to be in contact with respective ones of the second landing portions 231b of the plurality of second traces 230b illustrated in FIG. 2.

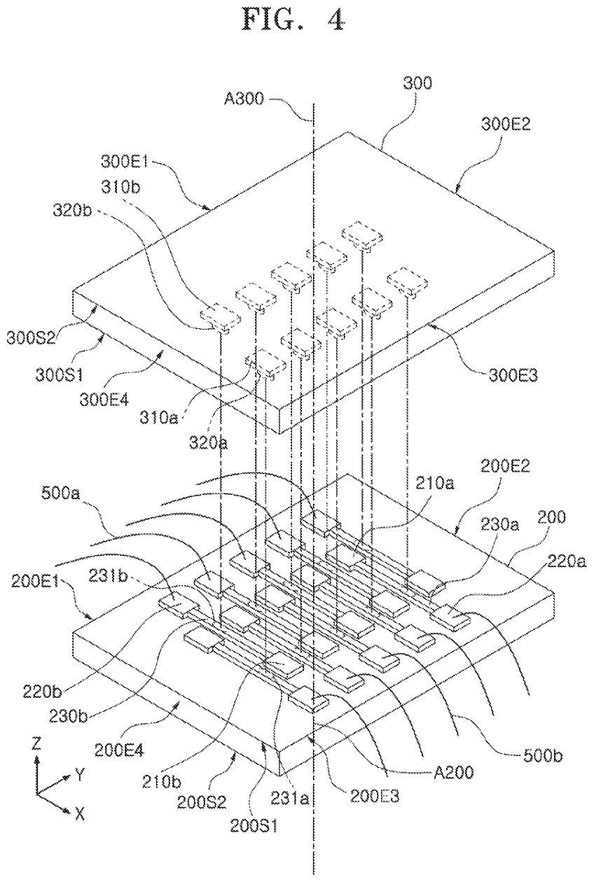

FIG. 4 is an exploded perspective view illustrating the lower chip 200 illustrated in FIG. 2 and the upper chip 300 illustrated in FIG. 3. An electrical connection structure of the lower chip 200 and the upper chip 300 as well as electrical paths between the lower chip 200 and the upper chip 300 will be described hereinafter with reference to FIG. 4. In order to avoid complexity in the drawing, the substrate 100 is not illustrated in FIG. 4.

In FIG. 4, in order to attach the upper chip 300 to the lower chip 200, the lower chip 200 may be disposed such that the top surface 200S1 of the lower chip 200 faces the upper chip 300 and the upper chip 300 may be disposed such that the top surface 300S1 of the upper chip 300 faces the lower chip 200. That is, the upper chip 300 may correspond to a flip chip. In addition, the each of the lower chip 200 and the upper chip 300 may have a cuboid shape and a predetermined thickness.

Referring to FIG. 4, the lower chip 200 and the upper chip 300 may have the same shape and the same size. In addition, the lower chip pads 210a and 210b may be disposed to have the same array as the upper chip pads 310a and 310b. As such, an array configuration of the plurality of first lower chip pads 210a and the plurality of second lower chip pads 210b on the top surface 200S1 of the lower chip 200 may be the same as an array configuration of the plurality of first upper chip pads 310a and the plurality of second upper chip pads 310b on the top surface 300S1 of the upper chip 300. In addition, the upper chip 300 may be stacked on the lower chip 200 such that a symmetric axis A200 of the lower chip 200 along a vertical direction (i.e., the z-axis direction) is consistent with a symmetric axis A300 of the upper chip 300 along the vertical direction (i.e., the z-axis direction). The symmetric axis A200 of the lower chip 200 means a vertical axis that passes through a central point of the lower chip 200 to be normal with respect to the top surface 200S1 of the lower chip 200. In such a case, the central point of the lower chip 200 may be located at a cross point of two diagonal lines of the lower chip 200 when viewed in a plan view. Moreover, the symmetric axis A300 of the upper chip 300 means a vertical axis that passes through a central point of the upper chip 300 to be normal with respect to the top surface 300S1 of the upper chip 300. In such a case, the central point of the upper chip 300 may be located at a cross point of two diagonal lines of the upper chip 300 when viewed in a plan view. That is, the upper chip 300 may be stacked on the lower chip 200 not to be offset relative to the lower chip 200.

Referring to FIG. 4, the upper chip 300 may be stacked on the lower chip 200 such that first to fourth edges 300E1, 300E2, 300E3, and 300E4 of the upper chip 300 are vertically aligned with first to fourth edges 200E1, 200E2, 200E3, and 200E4 of the lower chip 200, respectively. More specifically, the first edge 200E1 of the lower chip 200 and the first edge of 300E1 of the upper chip 300 may be located on a single vertical plane, and the second edge 200E2 of the lower chip 200 and the second edge of 300E2 of the upper chip 300 may be located on another single vertical plane. In addition, the third edge 200E3 of the lower chip 200 and the third edge of 300E3 of the upper chip 300 may be located on another single vertical plane, and the fourth edge 200E4 of the lower chip 200 and the fourth edge of 300E4 of the upper chip 300 may be located on another single vertical plane.

Referring to FIG. 4, the first bumps 320a may be disposed on respective ones of the first upper chip pads 310a to be in contact with respective ones of the first traces 230a. The first bumps 320a may also be attached to respective ones of the first landing portions 231a included in the first traces 230a. As such, first ends of the first bumps 320a may be attached to the first upper chip pads 310a, and second ends of the first bumps 320a may be attached to the first landing portions 231a. The second bumps 320b may be disposed on respective ones of the second upper chip pads 310b to be in contact with respective ones of the second traces 230b. The second bumps 320b may also be attached to respective ones of the second landing portions 231b included in the second traces 230b. As such, first ends of the second bumps 320b may be attached to the second upper chip pads 310b, and second ends of the second bumps 320b may be attached to the second landing portions 231b.

According to the above descriptions related to FIG. 4, the first upper chip pad 310a, the first bump 320a disposed on the first upper chip pad 310a, the first trace 230a including the first landing portion 231a being in contact with the first bump 320a, the first lower chip pad 210a connected to a first end of the first trace 230a, and the first wire bonding pad 220a connected to a second end of the first trace 230a may be electrically connected to each other to provide an electrical signal path. Similarly, the second upper chip pad 310b, the second bump 320b disposed on the second upper chip pad 310b, the second trace 230b including the second landing portion 231b being in contact with the second bump 320b, the second lower chip pad 210b connected to a first end of the second trace 230b, and the second wire bonding pad 220b connected to a second end of the second trace 230b may be electrically connected to each other to provide an electrical signal path. More extensively, the plurality of first upper chip pads 310a, the plurality of first bumps 320a disposed on respective ones of the plurality of first upper chip pads 310a, the plurality of first traces 230a including the first landing portions 231a being in contact with respective ones of the plurality of first bumps 320a, the plurality of first lower chip pads 210a connected to respective ones of first ends of the plurality of first traces 230a, and the first wire bonding pads 220a connected to respective ones of second ends of the plurality of first traces 230a may be electrically connected to each other to provide a plurality of electrical signal paths. Similarly, the plurality of second upper chip pads 310b, the plurality of second bumps 320b disposed on respective ones of the plurality of second upper chip pads 310b, the plurality of second traces 230b including the second landing portions 231b being in contact with respective ones of the plurality of second bumps 320b, the plurality of second lower chip pads 210b connected to respective ones of first ends of the plurality of second traces 230b, and the second wire bonding pads 220b connected to respective ones of second ends of the plurality of second traces 230b may be electrically connected to each other to provide a plurality of electrical signal paths.

Referring to FIG. 4, electrical signals between the lower chip pads 210a and 210b and the upper chip pads 310a and 310b may be transmitted through the bumps 320a and 320b. For example, the first upper chip pads 310a may be electrically connected to respective ones of the first lower chip pads 210a through the first bumps 310a disposed on the first upper chip pads 310a. Thus, the first lower chip pads 210a may receive electrical signals from the first upper chip pads 310a or may transmit the electrical signals to the first upper chip pads 310a. In addition, the second upper chip pads 310b may be electrically connected to respective ones of the second lower chip pads 210b through the second bumps 310b disposed on the second upper chip pads 310b. Thus, the second lower chip pads 210b may receive electrical signals from the second upper chip pads 310b or may transmit the electrical signals to the second upper chip pads 310b. more extensively, the upper chip pads 310a and 310b may be electrically connected to the lower chip pads 210a and 210b through the first and second bumps 320a and 320b attached to the upper chip pads 310a and 310b. Accordingly, electrical signals may be transmitted from the upper chip pads 310a and 310b to the lower chip pads 210a and 210b or vice versa.

Referring to FIGS, 1 and 4, if external signals including electrical signals generated by an external system are inputted to the outer connectors 600 of the substrate 100, then the external signals may be transmitted to the connection pads 110a and 110b through the interconnection lines (not shown) of the substrate 100. Because the connection pads 110a and 110b are connected to the wire bonding pads 220a and 220b of the lower chip 200 through the bonding wires 500a and 500b, the external signals transmitted to the connection pads 110a and 110b may be inputted to the lower chip 200 through the wire bonding pads 220a and 220b, the traces 230a and 230b, and the lower chip pads 210a and 210b. Some of the external signals inputted to the lower chip 200 may be transmitted to the upper chip pads 310a and 310b through the landing portions 231a and 231b (of the traces 230a and 230b) and the bumps 320a and 320b. In an embodiment, the external signals inputted to the first connection pads 110a may be transmitted to the second wire bonding pads 220b through the first bonding wires 500a. Subsequently, the external signals may be transmitted to the second lower chip pads 210b through the second traces 230b. Some of the external signals may also be transmitted to the second upper chip pads 310b through the second lower chip pads 210b and the second bumps 320b attached to the second landing portions 231b. In addition, the external signals inputted to the second connection pads 110b may be transmitted to the first wire bonding pads 220a through the second bonding wires 500b. Thereafter, the external signals inputted to the first wire bonding pads 220a may be transmitted to the first lower chip pads 210a through the first traces 230a. Some of the external signals inputted to the first wire bonding pads 220a may also be transmitted to the first upper chip pads 310a through the first bumps 320a attached to the first landing portions 231a.

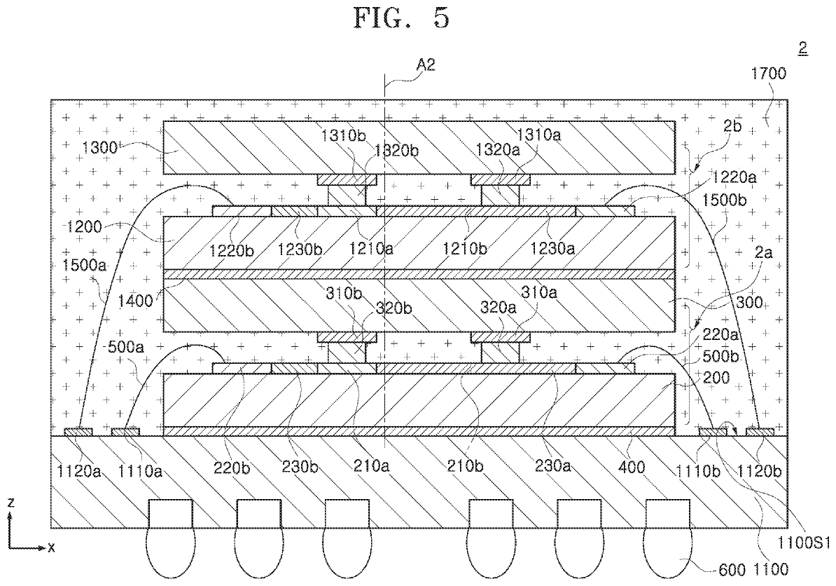

FIG. 5 is a cross-sectional view illustrating a semiconductor package 2 according to another embodiment of the present disclosure. In FIG. 5, the same reference numerals or the same reference symbols as used in FIGS. 1 to 4 denote the same elements.

Referring to FIG. 5, the semiconductor package 2 may be configured to further include a second lower chip 1200 stacked on the upper chip 300 and a second upper chip 1300 stacked on the second lower chip 1200, as compared with the semiconductor package 1 including the substrate 100, the lower chip 200, and the upper chip 300 which are described with reference to FIGS. 1 to 4. That is, the semiconductor package 2 may include the substrate 100, the lower chip 200 (i.e., a first lower chip), and the upper chip 300 (i.e., a first upper chip) described with reference to FIGS. 1 to 4 and may further include the second lower chip 1200 stacked on the first upper chip 300 and the second upper chip 1300 stacked on the second lower chip 1200.

Referring to FIG. 5, the semiconductor package 2 may include a substrate 1100, a first stack structure 2a disposed on the substrate 1100, and a second stack structure 2b disposed on the first stack structure 2a. The first stack structure 2a may include the first lower chip 200 and the first upper chip 300. The second stack structure 2b may include the second lower chip 1200 and the second upper chip 1300.

The semiconductor package 2 may include further include the adhesive layer 400 (i.e., a first adhesive layer), a second adhesive layer 1400, the first and second bonding wires 500a and 500b, third bonding wires 1500a, fourth bonding wires 1500b, the outer connectors 600, and an encapsulating member 1700. The first adhesive layer 400 may be disposed between the substrate 1100 and the first lower chip 200 to attach the first lower chip 200 to the substrate 1100. The second adhesive layer 1400 may be disposed between the first upper chip 300 and the second lower chip 1200 to attach the second lower chip 1200 to the first upper chip 300. Because the second adhesive layer 1400 is disposed between the first upper chip 300 of the first stack structure 2a and the second lower chip 1200 of the second stack structure 2b, the first stack structure 2a and the second stack structure 2b may be bonded to each other by the second adhesive layer 1400. The first and second bonding wires 500a and 500b may be disposed to electrically connect the substrate 1100 to the first lower chip 200. The third and fourth bonding wires 1500a and 1500b may be disposed to electrically connect the substrate 1100 to the second lower chip 1200. The outer connectors 600 may be attached to a bottom surface of the substrate 1100 to electrically connect the semiconductor package 2 to another semiconductor package or another substrate (e.g., a PCB). The encapsulating member 1700 may be formed to surround the first lower chip 200, the first upper chip 300, the second lower chip 1200, the second upper chip 1300, the first and second bonding wires 500a and 500b, and the third and fourth bonding wires 1500a and 1500b.

As described above, the first lower chip 200 of the first stack structure 2a may have substantially the same configuration as the lower chip 200 of the semiconductor package 1 illustrated in FIG. 1. In addition, the first upper chip 300 of the first stack structure 2a may have substantially the same configuration as the upper chip 300 of the semiconductor package 1 illustrated in FIG. 1. That is, the same reference numerals or the same reference symbols refer to the same elements throughout the specification. For example, the first adhesive layer 400 illustrated in FIG. 5 denotes substantially the same element as the adhesive layer 400 illustrated in FIG. 1. In addition, the lower chip pads 210a and 210b illustrated in FIG. 5 denote substantially the same elements as the lower chip pads 210a and 210b illustrated in FIGS. 1 and 2. Furthermore, the upper chip pads 310a and 310b illustrated in FIG. 5 denote substantially the same elements as the upper chip pads 310a and 310b illustrated in FIGS. 1 and 3. Thus, detailed descriptions of the same elements as previously mentioned with reference to FIGS. 1 to 4 will be omitted hereinafter.

Referring to FIG. 5, the second lower chip 1200 of the second stack structure 2b may have substantially the same configuration as the first lower chip 200 of the first stack structure 2a, and the second upper chip 1300 of the second stack structure 2b may have substantially the same configuration as the first upper chip 300 of the first stack structure 2a. Lower chip pads 1210a and 1210b disposed on the second lower chip 1200 may have substantially the same array as the lower chip pads 210a and 210b disposed on the first lower chip 200. In addition, wire bonding pads 1220a and 1220b disposed on the second lower chip 1200 may have substantially the same array as the wire bonding pads 220a and 220b disposed on the first lower chip 200. Moreover, traces 1230a and 1230b disposed on the second lower chip 1200 may have substantially the same array as the traces 230a and 230b disposed on the first lower chip 200. Furthermore, upper chip pads 1310a and 1310b disposed on the second upper chip 1300 may have substantially the same array as the upper chip pads 310a and 310b disposed on the first upper chip 300. Further, bumps 1320a and 1320b between the second lower chip 1200 and the second upper chip 1300 may also have substantially the same array as the bumps 320a and 320b between the first lower chip 200 and the first upper chip 300.

Referring to FIG. 5, the first lower chip 200 may be electrically connected to the substrate 1100 through the first and second bonding wires 500a and 500b. The first and second bonding wires 500a and 500b may be bonded to the wire bonding pads 220a and 220b of the first lower chip 200 and first and second connection pads 1110a and 1110b disposed on a top surface 1100S1 of the substrate 1100. The second lower chip 1200 may be electrically connected to the substrate 1100 through the third and fourth bonding wires 1500a and 1500b. The third and fourth bonding wires 1500a and 1500b may be bonded to the wire bonding pads 1220a and 1220b of the second lower chip 1200 and third and fourth connection pads 1120a and 1120b disposed on the top surface 1100S1 of the substrate 1100.

Referring to FIG. 5, the first upper chip 300 may be stacked on the first lower chip 200 in a vertical direction parallel with the z-axis such that an active surface of the first upper chip 300 faces an active surface of the first lower chip 200. In addition, the second upper chip 1300 may be stacked on the second lower chip 1200 in the vertical direction parallel with the z-axis such that an active surface of the second upper chip 1300 faces an active surface of the second lower chip 1200. In such a case, the first lower chip 200, the first upper chip 300, the second lower chip 1200, and the second upper chip 1300 may be stacked on the substrate 1100 in the vertical direction to share a single symmetric axis A2 extending in the vertical direction (i.e., the z-axis direction).

Referring to FIG, 5, there is disclosed a semiconductor package in which the two stack structures 2a and 2b having substantially the same configuration are stacked on the substrate 1100. In some other embodiments, there may be provided a semiconductor package in which a plurality of stack structures having substantially the same configuration as the first stack structure 2a (or the second stack structure 2b) are stacked on the substrate 1100. That is, there may be provided a semiconductor package in which three or more stack structures having substantially the same configuration as the first stack structure 2a (or the second stack structure 2b) are stacked on the substrate 1100.

As described above, according to the embodiments, a pair of semiconductor chips may be stacked such that active surfaces of the pair of semiconductor chips face each other, and the pair of semiconductor chips having the same size may be vertically aligned with each other such that one of the pair of semiconductor chips is not offset relative to the other of the pair of semiconductor chips. Because there is no offset in a stack structure of the pair of semiconductor chips, it may be possible to reduce a size of the semiconductor package and to increase an integration density of the semiconductor package. In addition, according to the embodiments described above, there may be provided a semiconductor package having a stack structure of a plurality of semiconductor chips even without using an extra structure or a through silicon via (TSV) technique. Thus, it may be possible to lower the manufacturing costs of the semiconductor package.

It may be possible to modify an array of the first and second lower chip pads of the lower chip and an array of the first and second upper chip pads of the upper chip. According to various modifications, the first and second lower chip pads may be arrayed in a zigzag fashion on an active surface of the lower chip, and first and second traces extending from the first and second lower chip pads may be provided. In such a case, the first and second traces may include landing portions to which the first and second upper chip pads of the upper chip are attached.

The first and second upper chip pads may be disposed on an active surface of the upper chip to have substantially the same array as the first and second lower chip pads of the lower chip. Because the first and second upper chip pads of the upper chip are attached to the landing portions of the first and second traces using the bumps, the first and second upper chip pads may be electrically connected to the first and second lower chip pads. In such a case, due to the attachment between the lower chip pads and the upper chip pads, the lower chip and the upper chip may be aligned with and bonded to each other without offset.

The inventive concept has been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all of distinctive features in the equivalent scope should be construed as being included in the inventive concept.

5

What is claimed is:

1. A semiconductor package comprising:
a lower chip; and
an upper chip stacked on the lower chip,
wherein the lower chip comprises:
lower chip pads arrayed in a plurality of lower columns on a top surface of the lower chip to have different horizontal axes;
wire bonding pads disposed on the top surface of the lower chip to be laterally spaced apart from the lower chip pads; and
traces disposed on the top surface of the lower chip to electrically connect the lower chip pads to the wire bonding pads,
wherein the upper chip comprises:
upper chip pads arrayed in a plurality of upper columns on a top surface of the upper chip to have different horizontal axes; and
bumps disposed on respective ones of the upper chip pads to be in contact with respective ones of the traces, and
wherein the upper chip is stacked on the lower chip such that the top surface of the upper chip faces the top surface of the lower chip.

2. The semiconductor package of claim 1,
wherein the lower chip pads arrayed in each of the plurality of lower columns are spaced apart from each other by a first distance;
wherein the upper chip pads arrayed in each of the plurality of upper columns are spaced apart from each other by a second distance; and
wherein the first distance is equal to the second distance.

3. The semiconductor package of claim 2, wherein the wire bonding pads are arrayed in a direction parallel with the plurality of lower columns; and
wherein the traces:
include landing portions to which the bumps are attached;
extend in a row direction intersecting the plurality of lower columns to pass through regions between the lower chip pads; and
electrically connect the lower chip pads to the wire bonding pads.

4. The semiconductor package of claim 1,
wherein the plurality of lower columns include a first lower column and a second lower column which are parallel with each other;
wherein the lower chip pads in the first and second lower columns are arrayed in a zigzag fashion;
wherein the plurality of upper columns include a first upper column and a second upper column which are parallel with each other; and
wherein the upper chip pads in the first and second upper columns are arrayed in a zigzag fashion.

5. The semiconductor package of claim 1,
wherein the lower chip and the upper chip have the same shape and the same size;
wherein the lower chip pads are disposed to have the same array as the upper chip pads; and
wherein the lower chip and the upper chip are stacked to share a single symmetric axis extending in a vertical direction which is normal with respect to the top surfaces of the lower chip and the upper chip.

6. The semiconductor package of claim 1, further comprising:
a substrate including connection pads and providing a place on which the lower chip and the upper chip are stacked;
an adhesive layer disposed between the substrate and the lower chip to attach the lower chip to the substrate;
bonding wires bonded to the connection pads and the wire bonding pads to electrically connect the lower chip to the substrate; and
an encapsulating member surrounding the lower chip, the upper chip, and the bonding wires.

7. A semiconductor package comprising:
a lower chip; and
an upper chip stacked on the lower chip,
wherein the lower chip comprises:
a first lower chip pad array including first lower chip pads arrayed in a column direction on a top surface of the lower chip;
a second lower chip pad array including second lower chip pads which are arrayed on the top surface of the lower chip to have horizontal axes different from horizontal axes of the first lower chip pads;
first wire bonding pads arrayed in the column direction on the top surface of the lower chip to be laterally spaced apart from respective ones of the first lower chip pads;
first traces disposed on the top surface of the lower chip to electrically connect the first lower chip pads to the first wire bonding pads;
second wire bonding pads arrayed in the column direction on the top surface of the lower chip to be laterally spaced apart from respective ones of the second lower chip pads; and
second traces disposed on the top surface of the lower chip to electrically connect the second lower chip pads to the second wire bonding pads,
wherein the upper chip comprises:
a first upper chip pad array including first upper chip pads arrayed in the column direction on a top surface of the upper chip;
a second upper chip pad array including second upper chip pads which are arrayed on the top surface of the upper chip to have horizontal axes different from horizontal axes of the first upper chip pads;
first bumps disposed on respective ones of the first upper chip pads to be in contact with respective ones of the first traces; and
second bumps disposed on respective ones of the second upper chip pads to be in contact with respective ones of the second traces, and
wherein the upper chip is stacked on the lower chip such that the top surface of the upper chip faces the top surface of the lower chip.

8. The semiconductor package of claim 7,
wherein the first lower chip pad array and the second lower chip pad array are disposed to be laterally spaced apart from each other;
wherein the first lower chip pads arrayed in the first lower chip pad array are spaced apart from each other by a first lower distance;
wherein the second lower chip pads arrayed in the second lower chip pad array are spaced apart from each other by a second lower distance;
wherein the first upper chip pad array and the second upper chip pad array are disposed to be laterally spaced apart from each other;
wherein the first upper chip pads arrayed in the first upper chip pad array are spaced apart from each other by a first upper distance;
wherein the second upper chip pads arrayed in the second upper chip pad array are spaced apart from each other by a second upper distance; and
wherein the first lower distance, the second lower distance, the first upper distance, and the second upper distance are all equal to each other.

9. The semiconductor package of claim 8,
wherein the first traces:
include first landing portions to which the first bumps are attached;
extend in a row direction intersecting the column direction to pass through regions between the second lower chip pads; and
connect the first lower chip pads to the first wire bonding pads, and
wherein the second traces:
include second landing portions to which the second bumps are attached;
extend in the row direction to pass through regions between the first lower chip pads; and
connect the second lower chip pads to the second wire bonding pads.

10. The semiconductor package of claim 7,
wherein the first lower chip pad array and the second lower chip pad array are disposed in a first lower column and a second lower column, respectively;
wherein the first lower chip pads in the first lower column and the second lower chip pads in the second lower column are arrayed in a zigzag fashion;
wherein the first upper chip pad array and the second upper chip pad array are disposed in a first upper column and a second upper column, respectively; and
wherein the first upper chip pads in the first upper column and the second upper chip pads in the second upper column are arrayed in a zigzag fashion.

11. The semiconductor package of claim 7,
wherein the lower chip and the upper chip have the same shape and the same size;
wherein the first and second lower chip pads are disposed to have the same array as the first and second upper chip pads; and
wherein the lower chip and the upper chip are stacked to share a single symmetric axis extending in a vertical direction which is normal with respect to the top surfaces of the lower chip and the upper chip.

12. The semiconductor package of claim 7, further comprising:
a substrate including connection pads and providing a place on which the lower chip and the upper chip are stacked;
an adhesive layer disposed between the substrate and the lower chip to attach the lower chip to the substrate;
bonding wires bonded to the connection pads and the wire bonding pads to electrically connect the lower chip to the substrate; and
an encapsulating member surrounding the lower chip, the upper chip, and the bonding wires.

13. A semiconductor package comprising:
a first stack structure including a first lower chip and a first upper chip stacked on the first lower chip; and
a second stack structure stacked on the first stack structure to include a second lower chip and a second upper chip stacked on the second lower chip,
wherein each of the first lowerchip and the second lower chip includes:
a first top surface;
lower chip pads arrayed in a plurality of columns on the first top surface to have horizontal axes different from each other;
wire bonding pads disposed on the first top surface to be laterally spaced apart from respective ones of the lower chip pads; and
traces connecting the lower chip pads to the wire bonding pads, and
wherein each of the first upper chip and the second upper chip includes:
a second top surface;
upper chip pads arrayed in a plurality of columns on the second top surface to have horizontal axes different from each other; and
bumps disposed on respective ones of the upper chip pads to land on respective ones of the traces.

14. The semiconductor package of claim 13,
wherein the plurality of columns in which the lower chip pads are arrayed include a first lower column and a second lower column;
wherein the lower chip pads in the first and second lower columns are arrayed in a zigzag fashion;
wherein the plurality of columns in which the upper chip pads are arrayed include a first upper column and a second upper column; and
wherein the upper chip pads in the first and second upper columns are arrayed in a zigzag fashion.

15. The semiconductor package of claim 13,
wherein the first lower chip and the first upper chip have the same shape and the same size;
wherein the second lower chip and the second upper chip have the same shape and the same size;
wherein the lower chip pads are disposed to have the same array as the upper chip pads; and
wherein the first lower chip, the first upper chip, the second lower chip, and the second upper chip are stacked to all share a single symmetric axis extending in a vertical direction which is normal with respect to the first and second top surface.

16. The semiconductor package of claim 13, further comprising:
a substrate including connection pads and providing a place on which the first lower chip, the first upper chip, the second lower chip, and the second upper chip are stacked;
a first adhesive layer disposed between the substrate and the first lower chip to attach the first lower chip to the substrate;
a second adhesive layer disposed between the first upper chip and the second lower chip to attach the second lower chip to the first upper chip;
bonding wires bonded to the connection pads and the wire bonding pads to electrically connect the first and second lower chips to the substrate; and
an encapsulating member surrounding the first and second lower chips, the first and second upper chips, and the bonding wires.
